(19) United States
(12) Patent Application Publication
(10) Pub. No.: US 2011/0061919 A1
(43) Pub. Date: Mar. 17, 2011

(54) Low temperature co-fired ceramics assembling system and method thereof

(75) Inventors: Gyu Man Hwang, Yongin-si (KR); Dae Hyeong Lee, Seoul (KR)

(73) Assignee: SAMSUNG ELECTRO-MECHANICS CO., LTD., Suwon (KR)

(21) Appl. No.: 12/654,899

(22) Filed: Jan. 7, 2010

(30) Foreign Application Priority Data
Sep. 11, 2009 (KR) 10-2009-0086001

(51) Int. Cl. H05K 1/18; H05K 3/30

(52) U.S. Cl. 174/260; 29/739; 29/832

(57) ABSTRACT

A low temperature ceramics substrate, a low temperature ceramics assembling system, and a method thereof in which a fixing member is formed on the bottom of an LTCC substrate, an insertion hole is formed at a coupled portion on a fixing member of the LTCC substrate coupled onto the heat sink, the fixing member is inserted into the insertion hole when the LTCC substrate and the heat sink are coupled to each other to firmly achieve alignment and fixation by the fixing member and a ceramic laminate assembling system includes a ceramic laminate substrate including an electronic component mounted on the bottom thereof and a fixing member is formed at one side thereof; and a heat sink including a sensor holder onto which the electronic component is held and an insertion groove is provided at a portion corresponding to the fixing member.

### CROSS-REFERENCE TO RELATED APPLICATIONS

This application claims the benefit of Korean Patent Application No. 10-2009-0086001 filed with the Korea Intellectual Property Office on Sep. 11, 2009, the disclosure of which is incorporated herein by reference.

### BACKGROUND OF THE INVENTION

1. Field of the Invention

The present invention relates to a low temperature co-fired ceramics assembling system having a housing structure for improving position accuracy of a low temperature co-fired ceramics (LTCC) substrate by mounting the LTCC substrate on an electric power steering (EPS) driving module during a process of manufacturing an electric module based on the low temperature co-fired ceramics (LTCC, hereinafter, referred to as ceramic laminate) substrate and a method thereof.

2. Description of the Related Art

A ceramic laminate (LTCC) is an abbreviation of low temperature co-fired ceramics. The low temperature co-fired ceramics element is the general term of elements manufactured by simultaneously sintering a metallic electrode and a ceramic substrate at a temperature of 1000° C. or less lower than a sintering temperature by 200° C. or more generally adopted at the time of sintering ceramics. The element manufactured above is used as a passive element for high-frequency communication and an electric control module.

A ceramic laminate module used for an electric control component can include a ceramic laminate constituted by a plurality of ceramic green sheets, an angle sensor mounted on the bottom of the ceramic laminate, and a heat sink that is provided below the ceramic laminate mounted with the angle sensor and is provided with a groove into which the angel sensor is inserted into a predetermined position. At this time, the angle sensor is a sensor that senses and outputs an angle at which a handle rotates by driver's operation.

Development of the module is tending to improvement in high performance, miniaturization, low price, and modulization of components. Electric modules recently used as components of vehicles are being developed to microminiaturization and multi-functionalization and related components implement microminiaturization and multi-functionalization by using a multi-layer (hereinafter, referred to as multi-layer structure) constituted by a plurality of substrates in order to correspond to the electric module. Further, mounting density and emission of heat generated from an IC are more effective than a generally used PCB. By this large advantage, the module is being applied to an electric power steering (EPS) system.

The EPS system is a system that provides high-speed drive stability to the driver by controlling steering force of a handle depending on a driving speed of a vehicle, that is, making steering force light in parking or low-speed driving and making the steering force heavy in high-speed driving by driving a motor through electronic control. Further, the EPS system is a system for improving fuel efficiency of the vehicle and actively coping with an electric automobile.

The EPS system has an advantage of improving the fuel efficiency by approximately 3 to 5%, reducing a maintenance cost, and achieving an environmental-friendly characteristic due to a decrease in weight of the vehicle and prevention of power loss. Further, the EPS system implements a decrease in weight and improvement of assemblability due to a decrease in the number of components. The EPS system can accurately control the steering force for each speed of the vehicle and improves steering performance by improving the high-speed drive stability. FIG. 1 is a diagram showing an assembling process of an LTCC substrate in the related art.

As shown in FIG. 1, in the case of LTCC in the related art, the LTCC substrate mounted with an angle sensor is mounted on a heat sink. Since a known housing for assembling a substrate is formed by simply assembling the LTCC substrate on a planar structure, workability is difficult at the time of assembling a substrate manual. Further, since a position and an angle are changed every time after assembling and an absolute position of the LTCC is changed after assembling, a concentricity error between a magnet and an angle sensor becomes large.

Since it takes a long time to harden epoxy applied to fix the LTCC substrate to the housing, it is possible to harden the epoxy within a short time and the LTCC substrate moves while hardening. As a result, the absolute position value of the LTCC is continuously changed. In addition, when the concentricity error between the magnet and the angle sensor assembled in the housing is generated, an error in detecting the angle sensor of the motor is generated.

### SUMMARY OF THE INVENTION

The present invention has been invented in order to overcome the above-described problems and it is, therefore, an object of the present invention to provide a low temperature ceramics substrate, a low temperature ceramics assembling system, and a method thereof in which a fixing member is formed on the bottom of an LTCC substrate, an insertion hole is formed at a coupled portion on a heat sink of the LTCC coupled onto the heat sink, the fixing member is inserted into the insertion hole when the LTCC substrate and the heat sink are coupled to each other substrate to firmly achieve alignment and fixation by the fixing member.

In order to achieve the above-described object, in accordance with one aspect of the present invention, there is a ceramic laminate substrate wherein an electronic component is mounted on the bottom of the ceramic laminate substrate and a fixing member is formed at one side of the ceramic laminate substrate. At this time, one or more fixing members are formed on the bottom. A plurality of elements are mounted on the top of the ceramic laminate substrate.

Meanwhile, in order to achieve the above-described object, in accordance with another aspect of the present invention, there is a ceramic laminate assembling system that includes a ceramic laminate substrate including an electronic component mounted on the bottom thereof and a fixing member is formed at one side thereof; and a heat sink including a component holder onto which the electronic component is held and an insertion groove is provided at a portion corresponding to the fixing member.

In order to achieve the above-described object, in accordance with yet another aspect of the present invention, there is a ceramic laminate assembling method that includes (a) preparing the ceramic laminate substrate including an electronic component mounted on the bottom thereof and a fixing member formed at one side thereof; (b) preparing a heat sink including a component holder for holding the electronic component and an insertion groove at a portion corresponding to the fixing member; and (c) mounting the heat sink on the bottom of the ceramic laminate substrate.

Herein, step (a) prepares the ceramic laminate substrate where one or more guide pins are formed, step (b) prepares the heat sink with one or more insertion grooves, and step (c) mounts the heat sink on the bottom of the ceramic laminate substrate while inserting the fixing member into the one or more insertion grooves.

In addition, step (a) prepares the ceramic laminate substrate with a plurality of elements mounted on the top thereof.

In accordance with the present invention, by coupling a heat sink with a ceramic laminate by using a fixing member, coupling precision between the ceramic laminate and the heat sink is improved, thereby increasing efficiency of a coupling operation.

Further, in accordance with the present invention, it is possible to prevent the ceramic laminate from being bent or twisted even after a hardening process performed after coupling the heat sink with the ceramic laminate by means of the fixing member that fixes the ceramic laminate and the heat sink.

In addition, in the present invention, since the ceramic laminate and the heat sink are always aligned and fixed to a fixed position, it is possible to improve reliability and merchantability of a product by minimizing the concentricity error between electronic components mounted on the bottom of the LTCC.

Accordingly, in accordance with the present invention, it is possible to improve productivity by lowering a defective rate generated at the time of coupling the heat sink with the ceramic laminate and save a manufacturing cost.

Further, since the fixing member removes movement of the LTCC substrate while epoxy applied to fix the LTCC substrate to a housing is hardened, an absolute position of the LTCC substrate is not changed.

Moreover, it is possible to improve efficiency of a substrate mounting operation at the time of assembling a housing substrate for a module, and shorten an operation time and improve the performance of the product.

In addition, it is possible to reduce a disposal cost in an end product by preventing an error item generated while assembling an electric module in the housing by modifying the shape of a housing for a module.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram showing an assembling process of an LTCC substrate in the related art;

FIG. 2 is a configuration diagram showing a configuration of a low temperature co-fired ceramics assembling system in accordance with an embodiment of the present invention;

FIG. 3 is a configuration showing a cross-sectional view of a ceramic laminate substrate in accordance with an embodiment of the present invention;

FIG. 4 is a flowchart for describing a method of assembling LTCC in accordance with an embodiment of the present invention;

FIG. 5 is a diagram showing a cross-sectional view before an LTCC substrate is coupled to a heat sink in accordance with an embodiment of the present invention; and

FIGS. 6A to 6C are perspective views showing the process of coupling a heat sink to a ceramic laminate in accordance with an embodiment of the present invention.

### DETAILED DESCRIPTION OF THE PREFERABLE EMBODIMENTS

A matter regarding to a configuration and an effect of the present invention will be appreciated clearly through the following detailed description with reference to the accompanying drawings illustrating preferable embodiments of the present invention. Hereinafter, an embodiment in accordance with the present invention will be described in detail with reference to the accompanying drawings.

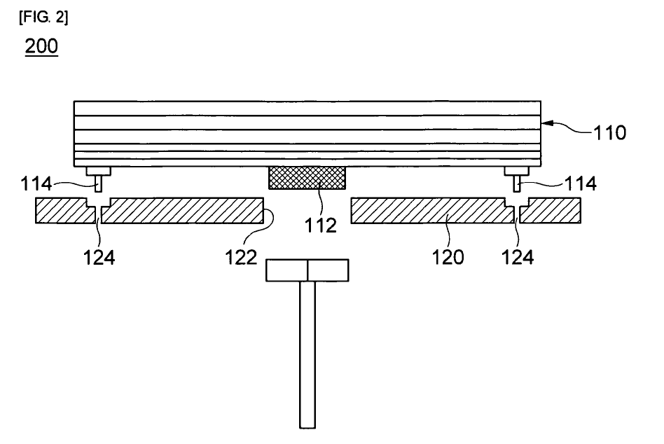

FIG. 2 is a configuration diagram showing a configuration of a low temperature co-fired ceramics (LTCC) assembling system in accordance with an embodiment of the present invention.

Referring to FIG. 2, the low temperature co-fired ceramics (LTCC) assembling system 200 in accordance with the present invention includes an LTCC substrate 110 and a heat sink 120.

The LTCC substrate 110 is mounted with an electronic component 112 on the bottom thereof and formed with a fixing member 114 at one side thereof.

Herein, the electronic component 112 may be soldered by a surface mount technology (SMT). The electronic component 112 may be, for example, an angle sensor that senses and outputs an angle of a handle rotated by a driver's operation, etc. At this time, the fixing member 114 may be, for example, a guide pin. For example, one or more guide pins may be formed at left and right sides of the bottom of the LTCC substrate 110, respectively.

A plurality of elements is mounted on the top of the LTCC substrate 110.

The LTCC substrate 110 mounted with the electronic component 112 generates heat by the electronic component 112. The heat is not properly emitted to the outside but is accumulated in the LTCC substrate 110, thereby deteriorating characteristics of the electronic component 112.

Therefore, the heat sink 120 may be provided in the lower part of LTCC substrate 110. The heat sink 120 has a function of emitting the heat, etc. transferred from the LTCC substrate 110 and the electronic component 112 to the outside. Therefore, the heat sink 120 preferably includes a material having a heat transfer coefficient so as to effectively remove the heat. For example, the heat sink may be made of the material including aluminum, copper, silver, gold, etc.

The heat sink 120 is provided with a component holder 122 at which the electronic component 112 of the LTCC substrate 110 is held and an insertion groove 124 at a portion corresponding to the fixing member 114 of the LTCC substrate 110 when the heat sink 120 is coupled to the LTCC substrate 110. At this time, the insertion groove 124 may a circular or rectangular shape.

The LTCC substrate 110 is held on the top of the heat sink 120 and the electronic component 112 is inserted into the component holder 122 to be coupled to each other. At this time, an adhesion member 130 may be provided on a junction interface between the LTCC substrate 110 and the heat sink 120. The adhesion member 130 may be made of epoxy or grease.

The fixing member 114 is coupled to the insertion groove 124 to fix the LTCC substrate 110 and the heat sink 120. The fixing member 114 may be provided in a guide pin type, but is not necessarily limited thereto.

FIG. 3 is a configuration diagram showing a cross-sectional view of a ceramic laminate substrate in accordance with an embodiment of the present invention.

Referring to FIG. 3, the LTCC substrate 110 according to the preset invention includes a plurality of green sheets 111 and 113 acquired by mixing ceramics with organic matter.

At this time, the green sheets 111 and 113 can be made of all ceramic materials without a particular limit, but the green sheets 111 and 113 are preferably made of a low temperature sintered ceramic material. The low temperature sintered ceramic material can be sintered at temperature of 1050° C. or lower and is a ceramic material which can be co-fired with silver, copper, or the like having low resistivity. In addition, the green sheets 111 and 113 may have a thickness of approximately 0.1 mm or 0.1 mm or less and is not necessarily limited thereto.

Thereafter, the green sheets 111 and 113 are processed with a desired size and a desired shape. At this time, the green sheets 111 and 113 can be separated into an upper green sheet 111 and a lower green sheet 113 where the fixing member 114 is formed.

Next, a pattern including a wiring circuit, a passive element, or the like is formed on the surface or inside of the upper and lower green sheets 111 and 113. At this time, the wiring circuit may penetrate the green sheets 111 and 113 in addition to on the surface and inside of the green sheets 111 and 113. The green sheets 111 and 113 are electrically connected to each other by the wiring circuit.

Next, after the upper and lower green sheets 111 and 113 are arranged and laminated, the upper and lower green sheets 111 and 113 are pressed by pressure of approximately 10 to 50 MPa at temperature of 60 to 80°. However, the temperature and the pressing pressure are exemplary and is not necessarily limited thereto.

When the upper and lower green sheets 111 and 113 integrated by being pressed as described above are sintered, the ceramic laminate 110 with the fixing member 114 is completed.

At this time, the sintering temperature is preferable in the range of temperature at which a low temperature co-fired ceramic material is sintered, for example, 800 to 1050° C. There is a fear in that a ceramic component of the upper and lower green sheets 111 and 113 will not be sintered at sintering temperature of 800° C. or lower and there is a fear in that when the sintering temperature is higher than 1050° C., metal particles of the pattern including the wiring circuit, the passive element, or the like in sintering are melted and dispersed into the upper and lower green sheets 111 and 113.

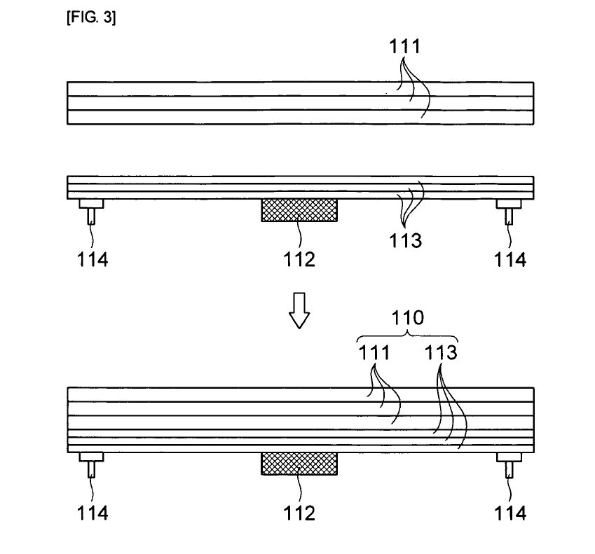

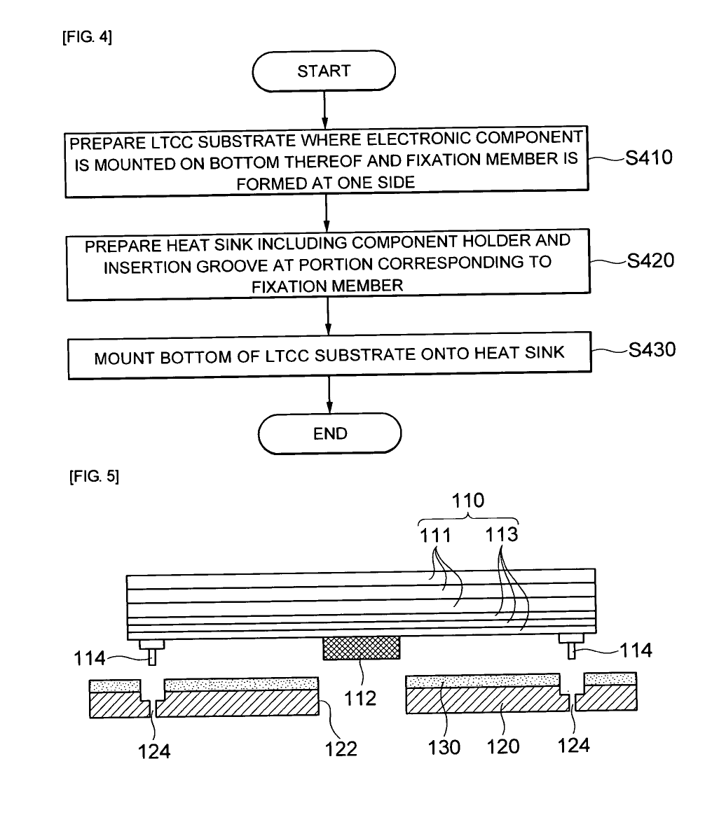

FIG. 4 is a flowchart for describing a method of assembling LTCC in accordance with an embodiment of the present invention. Referring to FIG. 4, the LTCC assembling system 100 prepares the LTCC substrate 110 where the electronic component 112 is mounted on the bottom thereof and the fixing member 114 is formed at one side thereof, as shown in FIG. 5 (S310).

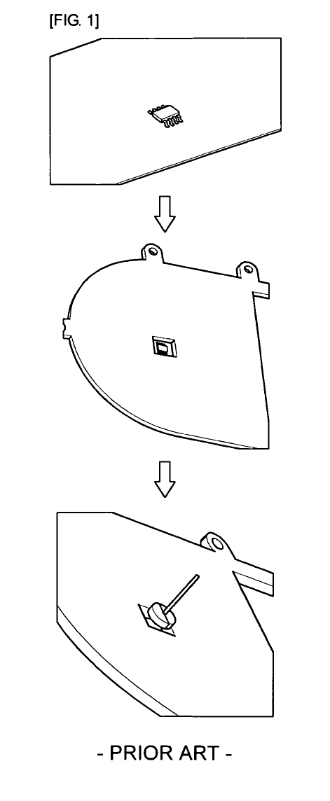

At this time, a plurality of elements is mounted on the top of the LTCC substrate 110 and as shown in FIGS. 1 and 2, one or more fixing members 114 are formed on the bottom of the LTCC substrate 110. As shown in FIG. 2, the electronic component 112 is mounted on the bottom of the completed LTCC substrate 110. At this time, the electronic component 112 as the angle sensor is mounted by the surface mount technology (SMT).

Herein, FIG. 5 is a diagram showing a cross-sectional view before the LTCC substrate is coupled to the heat sink according to an embodiment of the present invention.

Subsequently, as shown in FIG. 5, the component holder 122 for holding the electronic component 112 is provided and the heat sink 120 with the insertion groove 124 is provided in a part corresponding to the fixing member 114 (S320).

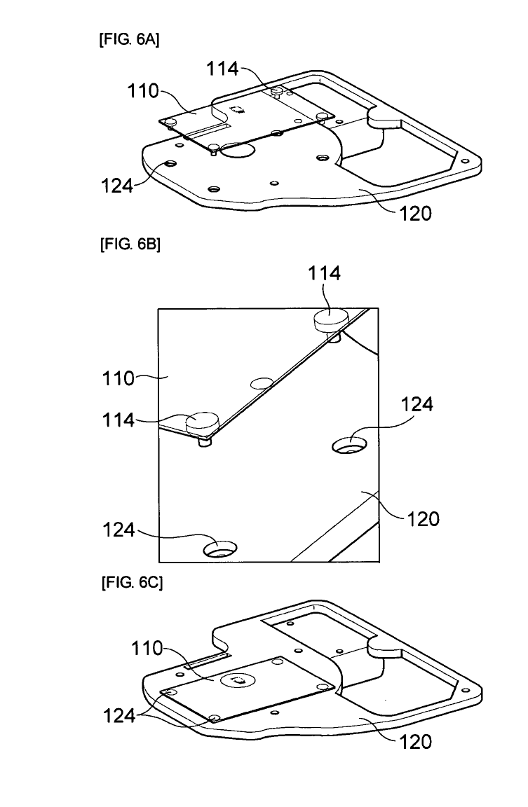

Referring to FIG. 5, the heat sink 120 is provided below the LTCC substrate 110. The insertion groove 124 of the heat sink 120 is provided at a position corresponding to the fixing member 114 and the component holder 122 is provided at a position corresponding to the electronic component 112. At this time, one or more insertion grooves 124 are provided in the heat sink 120 as many as the number of the fixing members 114. Therefore, as shown in FIG. 6A, before the heat sink 120 is coupled to the LTCC substrate 110, the LTCC substrate 110 and the heat sink 120 are positioned to correspond to each other for coupling. FIG. 6 is a perspective view showing a process of coupling a heat sink to a ceramic laminate according to an embodiment of the present invention.

In addition, the heat sink 120 is mounted on the bottom of the LTCC substrate 110 (S330).

As shown in FIG. 6B, the bottom of the LTCC substrate 110 is mounted on the heat sink 120 while the fixing members 114 of the LTCC substrate 110 are inserted into one or more insertion grooves 124 of the heat sink 120, respectively.

That is, after the adhesion member 130 is applied onto the junction interface of the LTCC substrate 110 mounted with the heat sink 120 and the electronic component 112, the LTCC substrate 110 and the heat sink 120 are coupled to each other as shown in FIG. 6C.

As such, when the LTCC substrate 110 and the heat sink 120 are fixed by the fixing member 114, the adhesion member 130 applied onto the junction interface between the LTCC substrate 110 and the heat sink 120 is hardened in a high-temperature atmosphere. At this time, the fixing member 114 may be made of a material which is not easily deformable to heat.

Likewise, the fixing member 114 for fixing the LTCC substrate 110 and the heat sink 120 is provided so as to improve coupling precision between the LTCC substrate 110 and the heat sink 120 and improve the reliability and merchantability of a product by minimizing the concentricity error between the electronic components 112. Further, even after hardening, it is possible to prevent the LTCC substrate 110 from being bent or twisted.

As described above, according to the present invention, it is possible to implement a low temperature ceramics substrate, a low temperature ceramics assembling system, and a method thereof in which a fixing member is formed on the bottom of an LTCC substrate, an insertion hole is formed at a coupled portion on a fixing member of the LTCC substrate coupled onto the heat sink, the fixing member is inserted into the insertion hole when the LTCC substrate and the heat sink are coupled to each other substrate to firmly achieve alignment and fixation by the fixing member.

As described above, although the preferable embodiments of the present invention have been shown and described, it will be appreciated by those skilled in the art that substitutions, modifications and changes may be made in these embodiments without departing from the principles and spirit of the general inventive concept, the scope of which is defined in the appended claims and their equivalents.

1. A ceramic laminate substrate, wherein an electronic component is mounted on the bottom of the ceramic laminate substrate and a fixing member is formed at one side of the ceramic laminate substrate.

2. The ceramic laminate substrate of claim 1, wherein one or more fixing members are formed on the bottom.

3. The ceramic laminate substrate of claim 1, wherein a plurality of elements is mounted on the top of the ceramic laminate substrate.

4. A low-temperature co-fired ceramics assembling system, comprising:
a ceramic laminate substrate including an electronic component mounted on the bottom thereof, wherein a fixing member is formed at one side thereof; and
a heat sink including a component holder onto which the electronic component is held and an insertion groove is provided at a portion corresponding to the fixing member.

5. A method for assembling a ceramic laminate substrate, comprising:
preparing the ceramic laminate substrate including an electronic component mounted on the bottom thereof and a fixing member formed at one side thereof;
preparing a heat sink including a component holder for holding the electronic component and an insertion groove at a portion corresponding to the fixing member; and
mounting the heat sink on the bottom of the ceramic laminate substrate.

6. The method for assembling a ceramic laminate substrate of claim 5, wherein
said preparing the ceramic laminate substrate prepares the ceramic laminate substrate where one or more guide pins are formed;
said preparing a heat sink prepares the heat sink with one or more insertion grooves; and
said mounting the heat sink mounts the heat sink on the bottom of the ceramic laminate substrate while inserting the fixing member into the one or more insertion grooves.

7. The method for assembling a ceramic laminate substrate of claim 5, wherein
said preparing the ceramic laminate substrate prepares the ceramic laminate substrate with a plurality of elements mounted on the top thereof.
